(19) United States
(12) Patent Application Publication
(10) Pub. No.: US 2008/0073795 A1
(43) Pub. Date: Mar. 27, 2008

(54) INTEGRATED CIRCUIT INTERCONNECTION DEVICES AND METHODS

(75) Inventors: PAUL A. KOHL, ATLANTA, GA (US); ATE HE, ATLANTA, GA (US); TYLER OSBORN, SMYRNA, GA (US)

Correspondence Address: TROUTMAN SANDERS LLP, 600 PEACHTREE STREET , NE, ATLANTA, GA, 30308, US

(73) Assignee: GEORGIA TECH RESEARCH CORPORATION, ATLANTA, GA (US)

(21) Appl. No.: 11/534,668

(22) Filed: Sep. 24, 2006

(51) Int. Cl. H01L 23/48

(52) U.S. Cl. 257/774

(57) ABSTRACT

Integrated circuit interconnection devices and methods are provided. An interconnection to connect components can comprise a first portion, a second portion, and a joining portion. The first portion can extend from a first component, and the first portion can be made with a single conductor. The second portion can extend from a second component, and the second portion can be made with the single conductor. The joining section can be disposed between the first portion and the second portion so that the first component and second component are interconnected to each other to form an interconnect. The joining section can be made of the single conductor so that the interconnect structure consists only of the single conductor. An interconnect can also be formed with two portions, and be formed to have a high-aspect ratio. Other embodiments are also claimed and described.

### TECHNICAL FIELD

The various embodiments of the present invention relate generally to integrated circuit fabrication and packaging techniques, and more particularly, to interconnection devices and interconnection fabrication methods used in fabricating integrated circuit (IC) devices.

### BACKGROUND

Solder is widely used in the electronics industry for attaching components to substrates or printed circuit boards in a flip-chip configuration. The melting point of solder, and its ability to adjust to lateral (self-alignment) and vertical (non-planar) surfaces makes it valuable in ball-grid array (BGA) packages and when utilizing epoxy substrates. Solder, however, has modest electrical properties and typically has inadequate mechanical bond strength. For example, copper-tin intermetallics have poor mechanical properties. Another drawback associated with solder is that it has low electro-migration resistances which can affect device lifespan and performance.

While solder has provided numerous benefits for conventional IC devices, solder's chemical and physical properties may not be adequate for future integrated devices. The International Technology Roadmap for Semiconductors (ITRS) projects that high performance chips in the very near future will require supply currents ranging from about 172 A to about 220 A. These current amounts will exceed the maximum allowable current density of solder (approximately ˜10⁴ A/cm²) given the projected number of input/output (I/O) interconnects.

Thus solder properties hinder the ability to produce faster and smaller integrated devices. For example, solder connections are limited to an aspect ratio of roughly unity so that high profile (large chip-to-substrate stand-off distance) is very difficult to obtain. High aspect ratio and non-spherical connections are needed for high I/O density and mechanically compliant IC-to-substrate connections. Indeed, very high frequency signal I/O, up to 88 GHz, are projected for future integrated devices.

Typically used solders also have poor mechanical strength. For example, tin and other solder-containing metals can form brittle intermetallics which fracture under high shear and normal stresses. Due to this poor mechanical strength, underfill is generally used to support solder connections. Underfill distributes thermo-mechanical stresses originating from the coefficient of thermal expansion (CTE) mismatch between the different materials. While providing additional mechanical strength to solder connections, underfill does create other device performance issues. For example, underfill affects the electrical environment (poorer permittivity and conductivity loss) of IC devices. Also, underfill and the processes used to supply underfill increase material and fabrication costs.

Several have tried to overcome the above discussed drawbacks associated with solder, but these processes still have associated shortcomings. For example, copper bonding (copper-to-copper fusion) can be used to produce all-copper connections. Copper-to-copper bonding involves achieving intimate contact between two clean, copper surfaces, at appropriate bonding temperatures, pressures, and sanitary conditions. To obtain adequate bonding between two copper surfaces, high temperature annealing of clean copper surfaces under pressure is required. High temperatures are preferred to create seamless copper joining, but these high temperatures are too high for cost-effective IC devices, and the high temperatures can destroy IC device components.

Another proposed solution involves a conventional interconnect structure with a reflowable solder cap on a copper surface. This solder cap avoids the high temperature copper-to-copper bonding problem and allows solder reflow at lower temperatures to enable union of copper surfaces. Due to the solder usage, however, the electrical and mechanical limitations of solder still exist. Further, a thin cap of solder on copper may not be able to compensate for z-axis non-uniformities (i.e., non-planar surfaces) or x, y-axis misalignment of parts.

While serving their respective purposes, these solutions are not advantageous because they still utilize solder techniques having electrical and mechanical drawbacks and also use very high temperatures not practical for IC device component manufacturing.

Accordingly, there is a need for interconnect structures and methods to fabricate interconnect structures that provide simple fabrication methods to produce interconnects having improved electrical and mechanical properties with fewer process steps and reduced costs. There is also a need for such structures and methods capable of compensating for non-planar surfaces encountered during interconnect fabrication It is to the provision of such interconnects and fabrication methods that various embodiments of the present invention are directed.

### BRIEF SUMMARY

Various embodiments of the present invention overcome the above-discussed and other drawbacks associated with conventional interconnects and interconnect fabrication methods. According to embodiments of the present invention, single metal interconnections and interconnection methods are provided. For example, electroless copper plating and annealing processes can provide substantially all-copper chip-to-substrate connections. The single metal (or conductor) can be any conductor in pure form, substantially pure form, or with specific impurities. As an example, all-copper structures can be composed of pure copper, substantially pure copper, copper with specific impurities, or copper alloys, such as copper-nickel alloys. Interconnects formed with embodiments of the present invention can have high aspect ratios to provide IC devices with high profile features (large chip-to-substrate stand-off distance).

The interconnections can comprise pillar sections (or pillars) joined together. As an example, pillars can be fabricated and electrolessly joined at ambient temperature. The joined pillars can then be annealed to increase mechanical strength. The anneal temperature used in some embodiments can be lowered to be compatible with epoxy boards (i.e. 150° C. to 250° C.) due to the electroless plating process. By joining the pillar sections together, embodiments of the present invention enable fabrication of interconnects having good electrical interfaces between pillar sections that may have varying distances between corresponding pillar sections. Thus, an advantageous feature of embodiments of the present invention enables interconnect fabrication to occur and overcome any fabrication variances that may occur when providing pillar sections.

Pillars can be formed to have high-aspect ratios according to embodiments of the present invention. High-aspect ratio can mean that the pillars can be formed to have a height greater than the width of a pillar. Due to the mechanical strength of the formed interconnects underfill or associated underfill processes may not be needed according to embodiments of the present invention. The height of the tall pillars, however, does facilitate use of underfill; thus, underfill may be used in accordance with some embodiments of the present invention.

Broadly described an interconnection structure to connect components according to some embodiments of the present invention can comprise various portions, including a first portion, a second portion, and a joining section. The first portion can extend from a first component and can consist of a single conductor. The joining section can be disposed between the first portion and a second component so that the first component and second component are interconnected to form an interconnect. The joining section can consist of the single conductor so that the interconnect consists only of the single conductor. The second portion can extend from the second component and be disposed between the second component and the joining section. In this embodiment, the first portion, the joining section, and the second portion can form an interconnect. And the second portion can consist of the single conductor so that the interconnect consists only of the single conductor. The joining section can be metallically bonded to the first and second portions so that the first and second components are electrically coupled.

Interconnects formed with embodiments can have various features. For example, the single conductor can be copper so that the interconnect is formed with copper. The joining section can have a greater cross-sectional area than one or both of the first portion or the second portion. The joining section can also have a central axis that is substantially aligned with a central axis associated with at least one of the first portion and the second portion. Also, the first portion can define a first axis and the second portion can define a second axis, and the interconnect can be formed with the first axis being misaligned with the second axis. The first and second portions can have different lengths and thicknesses.

According to some method embodiments of the present invention, a method to interconnect components can comprise providing a first interconnect section coupled to a first component, providing a second interconnect section coupled a second component, and electrolessly depositing a metal between the first interconnect section and the second interconnect section. The deposition can form a joining section that joins the first interconnect section and the second interconnect section to form an interconnect. The formed interconnect can couple the first component to the second component. The first interconnect section and the second interconnect section can be made from the same metal or other conductive material. Preferably, the first interconnect section or the second interconnect section are made from substantially pure copper.

Method embodiments can also include other features. For example, the first interconnect section and the second interconnect section can be formed by electroplating a metal. The metal can be copper. In addition, a rounded end or a tapered end can be formed on an end of the first interconnect section or the second interconnect section. One method embodiment can include annealing the interconnect. Also, the first interconnect section and the second interconnect section can be formed to have an aspect ratio ranging from approximately 0.1 to 10.

In still yet additional embodiments of the present invention, an integrated circuit package can comprise a substrate, a wafer, and a plurality of copper interconnects connecting the substrate to the wafer. Each interconnect can comprise a first copper component coupled to the substrate and a second copper component located between the first copper component and the wafer so that the first copper component and the second copper component couple the substrate and the wafer. A third copper component can be disposed between the first copper component and the second copper component. The third copper component can have a larger cross-sectional area than the cross-sectional area of the first copper component and the second copper component. Each interconnect can have approximately the same cross-sectional area, and define sidewalls having a length greater than the thickness of the interconnects.

Other aspects and features of embodiments of the present invention will become apparent to those of ordinary skill in the art, upon reviewing the following description of specific, exemplary embodiments of the present invention in conjunction with the accompanying figures.

### BRIEF DESCRIPTION OF THE DRAWINGS

FIG. 1 illustrates a cross-sectional view of an interconnect structure depicting various interconnect arrangements according to some embodiments of the present invention.

FIG. 2 illustrates an interconnect structure formed in accordance with some embodiments of the present invention.

FIG. 3 illustrates a build-up process to fabricate an interconnect according to some embodiments of the present invention.

FIG. 4 illustrates a logical flow diagram depicting a method to fabricate an interconnect structure according to some embodiments of the present invention.

### DETAILED DESCRIPTION OF PREFERRED & ALTERNATIVE EMBODIMENTS

Referring now to the figures, wherein like reference numerals represent like parts throughout the several views, exemplary embodiments of the present invention will be described in detail. Throughout this description, various components may be identified having specific values or parameters, however, these items are provided as exemplary embodiments. Indeed, the exemplary embodiments do not limit the various aspects and concepts of the present invention as many comparable parameters, sizes, ranges, and/or values may be implemented.

Various embodiments of the present invention provide interconnection structures and associated fabrication methods for use in IC packages. Metal pillars can be fabricated using electroplating deposition techniques and the metal pillars can be electrolessly joined at ambient temperature. Embodiments of the present invention include an electroless copper plating and annealing process to fabricate all-copper chip-to-substrate connections. Thus embodiments of the present invention enable interconnection structures to be fabricated at temperatures compatible with epoxy boards (i.e., about 150° C. to about 250° C.) and IC device components. Atomic mixing of the metal pillars during the plating process enables low process annealing temperatures.

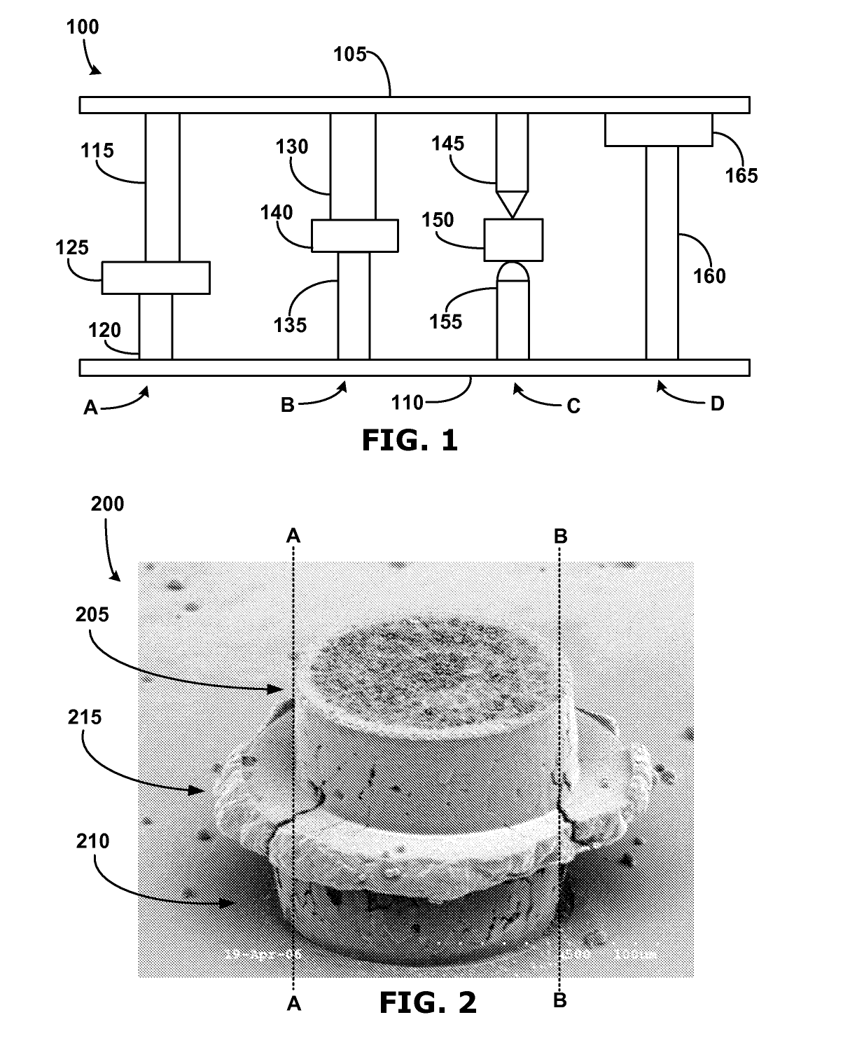

FIG. 1 illustrates a cross-sectional view of an interconnect structure 100 depicting various interconnect arrangements according to some embodiments of the present invention. The structure 100 generally comprises four interconnects A, B, C, and D illustrated in various fabrication arrangements. Interconnect A depicts an interconnect formed with misaligned pillars having different heights. Interconnect B depicts an interconnect formed with substantially aligned pillars having approximately equal heights. Interconnect C depicts an interconnect formed with pillars having shaped ends. And interconnect D depicts an interconnect formed with one pillar and a joining portion. It should be understood that an IC device preferably includes a plurality of interconnects and that even though single interconnect arrangements are discussed herein, the aspects, concepts, and principles discussed herein can apply to multiple interconnects.

Interconnects according to embodiments of the present invention can be used to connect multiple components. The components can be different devices and alternatively can be different components within an IC packaged device. Components can include integrated circuits, semiconductor wafers, substrates, or any other items to be electrically connected or coupled. Typically, interconnects connect components by having ends attached, bonded, or coupled to a surface of a component. As shown in FIG. 1, the structure 100 also comprises a first surface 105 and a second surface 110. The surfaces 105, 110 can be surfaces of substrates, semiconductor wafers (such as silicon), integrated circuits, or many other components capable of being coupled together. The interconnects A, B, C, and D as illustrated have certain sections or components proximate to surfaces 105, 110 that contact the surfaces, such as components 115 and 165.

Generally, interconnects A, B, C, and D include several sections or components. Each interconnect can include a first pillar section 115, 130, and 145 that extends from the first surface 105 and a second pillar section 120, 135, and 155 that extends from the second surface 110 as shown by interconnects A, B, and C. Alternatively, as shown by interconnect D, an interconnect may only comprise a single pillar section 160. The pillar sections may also be referred to as pillars, sections, interconnection sections, or components herein.

The pillar sections 115, 120, 130, 135, 145, 155, 160 can have various physical properties. Indeed, the pillar sections can have the same or substantially the same physical properties (e.g., aspect ratio, height, thickness, cross-sectional shape, end shape, etc.) as a respective pillar section, or alternatively, the pillar sections can have different physical properties. For example, pillar sections 115, 120 can have approximately the same thickness and have a square cross-sectional shape to form a square-shaped pillar.

Alternatively, pillar sections 115, 120, 130, 135, 145, 155, 160 can have differing physical properties. For example the pillar sections can have different heights, different cross-sectional shapes, and different end shapes. As an example, pillar sections 115, 120 have different heights and are misaligned such that the central axis and sidewalls of pillar sections 115, 120 are not aligned (discussed in greater detail with reference to FIG. 2). As another example, pillar section 145 has a tapered end and pillar section 155 has a rounded end. In still yet another embodiment, pillar section 130 has a different thickness than pillar section 135.

As mentioned above, an advantageous feature of embodiments of the present invention allows fabrication of continuous interconnects due to manufacturing variances resulting in differing physical properties that may occur when fabricating pillar sections. Also, pillar sections having different physical properties may provide certain advantageous features including beneficial fabrication process steps, low fabrication process times, or high mechanical strength properties. The pillar sections can be tapered, made from different copper alloys, or a collar (such as a polymer collar) can be formed around the pillar sections. In addition, the height, width, and elastic properties of the pillars can be chosen so that the two surfaces 105, 110 (or two interconnected components or devices) have a desirable compliance (i.e., can withstand certain shear forces).

Other components that interconnects A, B, C, and D generally comprise are the joint sections 125, 140, 150, 165. The joint sections may also be referred to as components, sections, or portions herein. The joint sections can be disposed or situated between respective pillar sections in a joint area such as joint sections 125, 140, and 150. Alternatively, the joint sections can be disposed or situated between a pillar section and a surface such as joint section 165. The joint sections 125, 140, 150, 160 can be a fillet of metal or other conductive material capable of filling a joint area. The joint area can be an area between ends of pillar sections or an area between a pillar section and a surface of a component. For example, joint section 125 is formed in the joint area between the ends of pillar sections 115, 120, and joint section 165 is formed between pillar 160 and surface 105.

The joint sections 125, 140, 150, 160 are preferably bonded or coupled to the pillar sections 115, 120, 130, 135, 145, 155, 165 as shown in FIG. 1. Such contact enables coupling of the first surface 105 to the second surface 110 by interconnects A, B, C, and D. Coupling of the first surface 105 to the second surface 110 enables electrical current to flow between the first surface 105 and the second surface 110.

The joint sections can also have various properties. For example, the joint sections 125, 140, 150, 165 can have the approximately the same or a different cross-sectional area as a corresponding pillar section. Due to current fabrication processes it is typical that the joint sections may have greater cross-sectional areas. The joint section 125, 140, 150, 165 cross-sectional area may depend on the shape of the pillar sections such that the geometry of formed joint sections 125, 140, 150, 165 may be controlled in concert with other fabrication parameters (e.g., deposition rate and deposition process). Joining sections can also have a central axis that is substantially aligned with a central axis of pillars, such as shown in Interconnects B and C.

Interconnects A, B, C, and D can be formed from a single metal or single conductor. The single metal can include a pure version, substantially pure version, or an impure version of the metal. The single conductor can include a pure version, substantially pure version, or an impure version of the metal. For example in an exemplary embodiment, the interconnects A, B, C, and D can be formed of only copper, copper alloys, or copper with specific impurities to improve pillar properties (e.g., physical strength or electrical conductivity). Copper interconnects provide mechanically strong connections and also provide advantageous electronic connections in a cost-efficient manner. Other metals can also be used in accordance with other embodiments including nickel, gold, silver, indium, palladium, or alloy combinations thereof. When better electrical performance is desired it may be preferable to utilize pure or substantially pure metal, whereas when certain physical benefits, such as lower melting point or increased mechanical strength, it may be preferable to utilize an alloy.

FIG. 2 illustrates an interconnect structure 200 formed in accordance with some embodiments of the present invention. The interconnect structure 200 generally comprises a first pillar section 205, a second pillar section 210, and a joint section 215. As shown, the joint section 215 is located between the first and second pillar sections 205, 210. The first pillar section 205 and the second pillar section 210 can have approximately the same shape, height, thickness, and cross-sectional area as shown in FIG. 2. Alternatively, these parameters can differ in other embodiments.

Also as shown, the joint section 215 can have a greater thickness relative to the thickness of the first pillar section 205 and the second pillar section 210. In some embodiments, it is preferable that the joint section 215 have a greater thickness relative to the thickness of the first pillar section 205 and the second pillar section 210. For example, having a joint section 215 with a thickness greater than pillar sections 205, 210 enables the capability to create a bond between pillar sections 205, 210 that are misaligned such that the central axes of pillar sections 205, 210 are not substantially aligned. As shown in FIG. 2, lines A-A and B-B further illustrate misalignment between pillar section 205, 210 in that the sidewalls of the pillar sections 205, 210 are not substantially aligned. Due to the thickness of (or width or diameter) joint section 215 being greater than that of the pillar sections 205, 210, it is possible to provide an interconnection 200 having misaligned portions.

The inventors have discovered that slight misalignment does not detract from the physical or electrical performance of the interconnection 200. Indeed, the greater thickness of the joint section 215 can provide increased conductivity and pillar strength. Further, due to the process of forming the joint section, the pillar sections do not need to have uniform planar surfaces since formation of the joint section can deposit metal in a non-uniform surface. Similarly, the pillar sections do not all need to have the same uniform height since formation of the joint sections can overcome any drawbacks associated with uneven heights and non-planar surfaces.

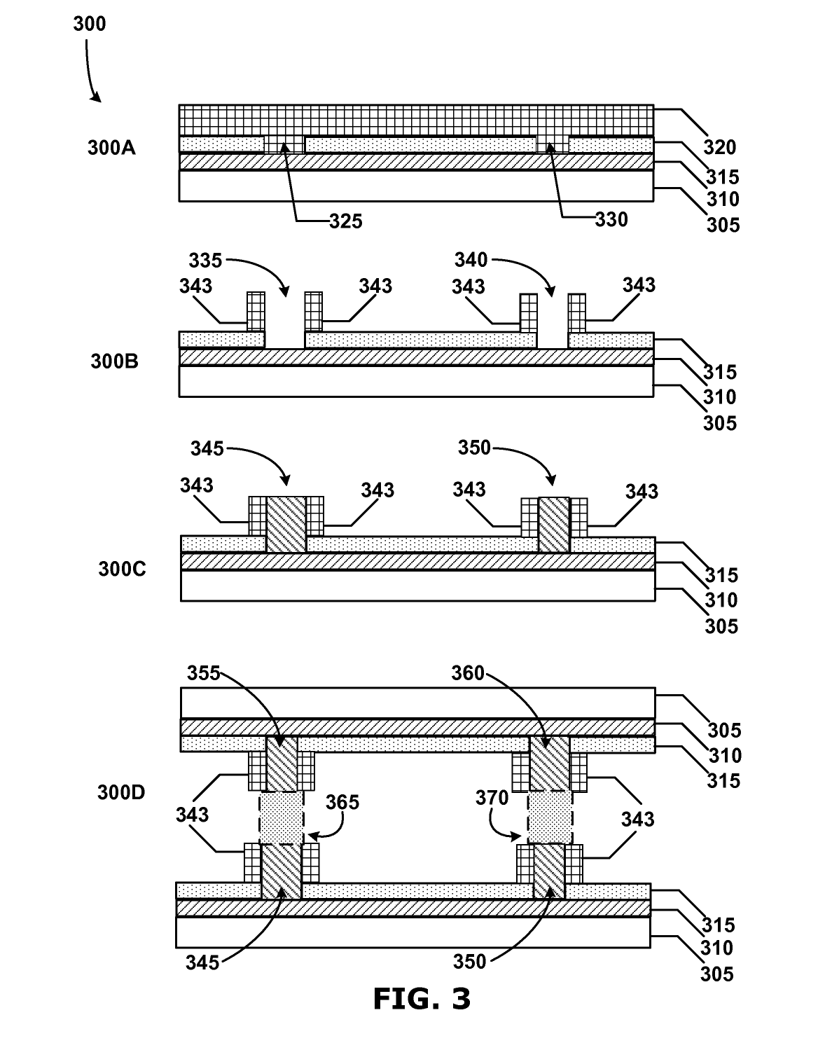

FIG. 3 illustrates a build-up process 300 to fabricate an interconnect according to some embodiments of the present invention. The process can comprise creating high-aspect ratio copper pillars using polymer molds with electroplating deposition, joining copper pillars to bridge gaps between pillars with electroless plating deposition, and annealing and recrystallizing joints between pillars to provide additional mechanical strength. It will be understood that process 300 is only one process implementation embodiment of the present invention and that other process embodiments are also possible. Also, process 300 can be performed in various orders and utilize additional process materials and parameters in fabricating interconnects.

The process 300 can begin by depositing several layers on a surface 305 as shown in 300A. The surface 305 can be a surface of a substrate, a semiconductor wafer (such as silicon), or other component to be coupled to another component. The several layers can include a three component layer of titanium/copper/titanium having approximate thicknesses of 30 nanometers, 1000 nanometers, and 10 nanometers, respectively. This three component layer can be sputtered on the wafer 305 for adhesive purposes and to provide a base layer of copper on the surface 305.

Other materials can be substituted for the components of the three layer surface. For example, other metals and alloys may be substituted for the copper. Similarly, chromium or other adhesive substances can be used in place of the titanium to improve adhesion to the surface 305. The copper layer 310 is illustrated in FIG. 3 but the adhesive layers (titanium and chromium) are not. It should be understood by those skilled in the art that the location of adhesive layers can be located on either side of the copper layer 310. In addition, for brevity, the discussion herein does not include discussion of the adhesive layers as those skilled in the art will understand that embodiments of the present invention can utilize various adhesive layers and materials.

A silicon dioxide layer 315 can be applied on the copper layer 310 as shown in 300A. The silicon dioxide layer 315 can protect the copper layer 310 and be used to form apertures 325, 330. The apertures 325, 330 can be used in fabricating or forming pillar structures (as discussed in greater detail below). The apertures 325, 330 can be formed in various geometric shapes depending on the shape of the desired pillar structures and can be matched to the desired shape of the pillar structures to be formed. The apertures 325, 330 allow access to the copper layer 310. The silicon dioxide layer 315 can have a thickness of approximately 1.5 micrometers, and can be deposited by plasma enhanced chemical vapor deposition (PECVD) at approximately 250° C. Other layer thickness and deposition methods may be used in alternative embodiments.

Next, a photoresist layer (not shown) can be applied onto the silicon dioxide layer 315. For example, Microposit SC1813 photoresist (Shipley Corporation) can be applied on the silicon dioxide surface. Once applied on the silicon dioxide layer 315, the photoresist can be patterned to yield a pre-determined pattern of the silicon dioxide. After photo-patterning the photoresist layer, buffered oxide etch (BOE) can etch the silicon dioxide layer 315 in the exposed areas. The etching can result in the formation of two apertures (or cavities) 325, 330 enabling open access to the copper layer 310. It should be understood that additional apertures 325, 300 can be formed to match the number of desired pillar structures to be formed or for other fabrication purposes. Remaining photoresist can be removed in an acetone rinse after aperture formation.

After forming the apertures 325, 330, molds 335, 340 can be formed according to process 300 as shown in 300B. The molds can be formed with a polymer material 320 and generally comprise polymer sidewalls 343 located proximate apertures 325, 330. The polymer material 320 can be a layer of Avatrel 2195P polymer (available from Promerus, LLC in Brecksville, Ohio) having a thickness ranging from about 1 micrometer to about 500 micrometers. Many other polymers and photoresists, such as SU-8 photoresist or AZ4620 photoresist, may also be utilized in accordance with embodiments of the present invention.

The polymer material 320 can be spun on top of the patterned silicon dioxide layer 315. The polymer spin rate can be about 500 rpm for about ten seconds followed by about 1000 rpm for about 60 seconds. After a softbake at approximately 40 minutes on a hotplate at about 100° C., a UV exposure dose can be applied to the polymer 320. The UV exposure can be about 250 mJ/cm² (365 nm irradiation). The polymer 320 can then be subjected to a post exposure bake at 100° C. for approximately twenty minutes, which can be followed by ultrasonic developing to produce high-aspect ratio, hollow-core polymer plating molds 335, 340.

Polymers used according to embodiments of the present invention are preferably capable of producing high aspect ratio structures with substantially vertical sidewalls. Such polymers enable production of tall, mechanically compliant interconnections, such as IC-to-substrate copper interconnections. The polymers are also preferably tolerant to long exposures to a plating bath. For example, Avatrel 2195P can be used as a polymer to form the plating molds 335, 340 because it easily forms high aspect ratio structures and has excellent stability in numerous plating solutions. Pillar structures can be fabricated to have aspect ratios (height/width) ranging from approximately 0.1 to approximately 10 with various embodiments of the present invention. The thickness of the polymer layer can be altered to produce pillars having desired heights.

The polymer plating molds 335, 340 can be adjusted to provide pillar structures having various physical properties. For example, the molds 335, 340 can be made with heights ranging from about 1 micrometer to about 500 micrometers and thicknesses (or width or diameter) ranging from about 1 micrometer to about 200 micrometers. The molds enable production of interconnects having various thicknesses. The molds 335, 340 illustrated in 300B-D are shown to be situated on either side of apertures 325, 330, and the distance between the molds can vary according to the desired aspect ratio of the pillar structures to be formed. The molds 335, 340 can be arranged in many shapes to produce pillars having various cross-sectional shapes according to embodiments of the present invention. For example, the molds 335, 340 can be formed in various three-dimensional shapes such as cylinders, cubes, prisms or in coaxial structures such as square and cylindrical coaxial structures.

It is preferable that the molds 335, 340 have sidewalls 343 located proximate the apertures 325, 330 to define the molds 335, 340. As shown, the sidewalls 343 are substantially vertical. The sidewalls 343 can be angled or slanted according to other embodiments, thus allowing the molds 335, 340 to define shapes of pillar structures formed in the molds 335, 340. The molds can also have complete peripherals sidewalls surrounding the periphery of apertures 325, 330. Thus, the sidewalls 343 of the molds 335, 340 can also be adjusted to form a pillar structure having a desired geometric shape.

After forming the molds 335, 340, the molds 335, 340 can be filled to form pillar structures 345, 350 as illustrated in 300C. For example, electroplating deposition can fill the polymer plating molds 335, 340 by depositing metal (or another conductive material) in the molds to produce pillar structures 345, 350. Preferably copper is electroplated to fill the cavities defined by the molds 335, 340. Alternatively, other metals and metal alloys can also be utilized such as gold, silver, palladium, indium, zinc, and alloy combinations thereof. Various plating methods may be chosen to elucidate various pillar geometries for the ends or tops of the pillars such as rounded or tapered (as illustrated by pillars 145, 150 in FIG. 1). The electroplating solution can contain 0.5M H₂SO₄, 0.5M CuSO₄, 0.25M brightener, and 0.25M carrier depending upon the actual substance being used during electroplate deposition. In addition, electroplating solutions containing a variety of additives and differing acid types or molarities may be used.

The electroplating process can occur according to various process parameters according to various embodiments of the invention. For example, the pH of the electroplating bath can be approximately 1.5, and alternatively the pH can range the full pH scale (1 to 14). Electroplating is preferably performed at approximately 2 milliamps constant current for about 20 hours at room (ambient temperature) with copper. Other current and time parameters can be used in other embodiments and may used with other metals. Electroplating should last as long as so that enough metal has been deposited to completely fill the molds 335, 340 to form pillars 345, 350. The metal deposition rate depends on current density as the higher the current density less time is need for deposition while with lower current densities, more time is needed for sufficient deposition. Depending on the metal used to form the pillar structures, high current densities may not be appropriate in all instances as low current densities may be more appropriate to ensure quality of the formed pillar structure.

When the pillar structures 345, 350 are sufficiently formed, the pillar structures 345, 350 can be joined to corresponding pillar structures 355, 360 as shown in 300D. Corresponding pillar structures 355, 360 can be formed similarly as pillar structures 345, 350 as discussed above and as labeled in 300D. Corresponding pillar structures can mean a pair or set of pillars that are placed in proximity to each other to be joined, such as pillars 345 and 355, and pillars 350 and 360. The corresponding pillar structures can be aligned using a flip chip bonder and held in place using wax. The wax can temporarily hold the bonded chips and be removed later during an annealing process. In other embodiments, other alignment methods to align and hold the formed pillars in place can also be used.

Once the corresponding pillar structures are aligned sufficiently, they can be joined to fill gaps between pillars. Preferably, the pillar structures are joined using electroless copper plating in accordance with exemplary embodiments of the present invention. For example, a copper sulfate, ethylenediaminetetraacetate (EDTA), formaldehyde electroless bath at approximately 45° C. and 12.5 pH can be used for about 6 hours to join the two pillar structure and dispose a fillet of copper in the joint area between the two pillar structures. That is, electrolessly plate deposition merges the two pillar structures together and forms a metal to metal joint. Other electrolessly plating bath parameters are also possible in accordance with embodiments of the invention. It is preferable that the electroless deposition process be continued until enough metal has been deposited to completely fill the gaps or joint areas between pillars.

After the pillar structures have been sufficiently joined by electroless plate deposition to form interconnects 365, 370, the interconnects 365, 370 can be subjected to an annealing process. The annealing can recrystallize the joint formed between the pillar structures to strengthen the interconnects 365, 370. The copper pillar structures can be annealed at various temperatures in a nitrogen environment, for example. Alternatively, annealing can occur in other environments and at other temperatures. Typically about one hour is sufficient to enable recrystallization of the joint to occur. The polymer sidewalls 343 can be also be removed during or prior to annealing the formed interconnects 365, 370 at sufficient temperatures for polymer decomposition.

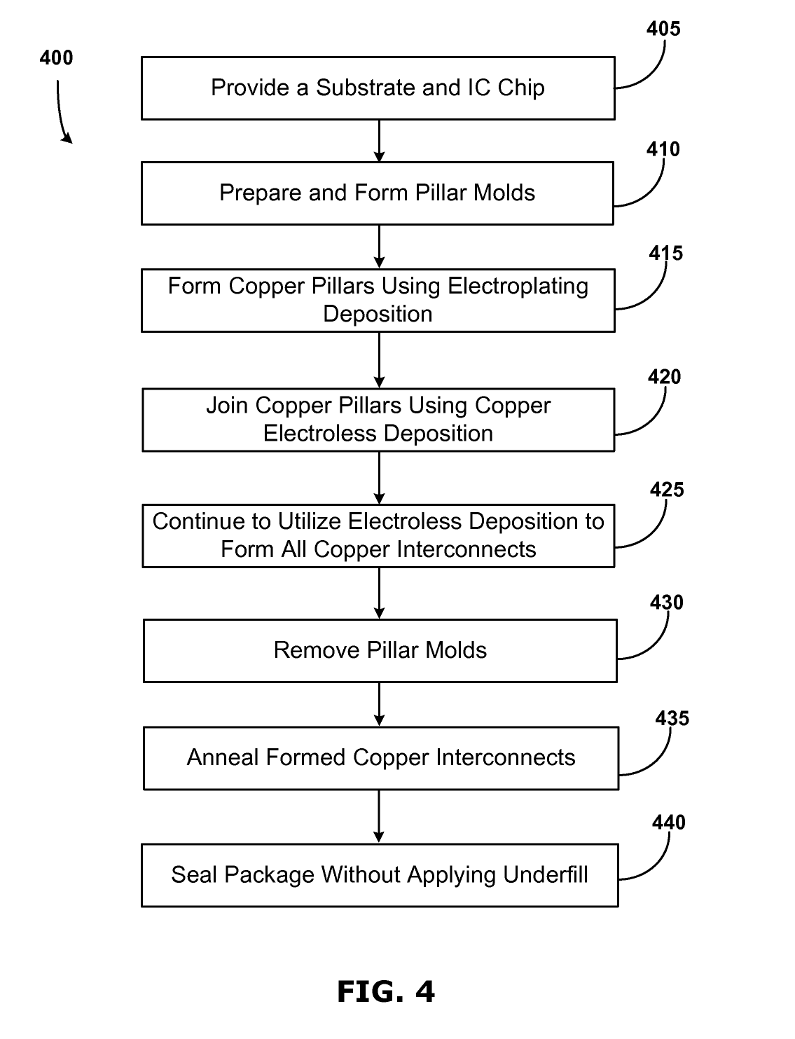

FIG. 4 illustrates a logical flow diagram depicting a method 400 to fabricate an interconnect structure according to some embodiments of the present invention. Embodiments of the present invention provide a fabrication process to obtain all-copper chip-to-substrate connections. The method 400 can initiate at 405 by providing a substrate and an IC chip to be bonded. Next pillar molds can be prepared and formed on the substrate and IC chip at 410.

Copper pillar structures can then be fabricated through electroplating in a polymer mold at 415. A copper electroless plating deposition technique can join the copper pillar structures to form an interconnect between components at 420. The electroless plating deposition can continue at 425 to form an all copper interconnect structure, and then the pillar molds can be removed at 430. The formed interconnect can be subjected to an annealing process at 435 to ensure sufficient bonding of the formed copper interconnect. Lastly, the package containing the coupled substrate and IC chip can be sealed without applying any underfill between the substrate and IC chip. In other embodiments, it may be desirable to use underfill and the high aspect ratio interconnects facilitate ability to used underfill. Fabrication process 400 can compensate for misalignment and height variations of the pillar structures thereby providing a simpler fabrication method.

As discussed herein, an advantageous feature of the present invention is the use of the electroless joining process to fill gaps between pillars to form interconnects. Sufficiently joining pillars ensures adequate physical bonding between pillars to enable electronic coupling. To examine certain fabricated pillars, the inventors cross-sectioned pillars by grinding and polishing them to examine the joint between the two surfaces. The inventors observed some small voids in the center of the electroless metal (forming joint area between pillar structures) at higher magnifications such as 50×. The small voids were restricted to a vertical height matching the height of the electroless plating region seen on the edge of the pillar structure. The number and size of voids in the electroless plated region varied for different samples. The conditions for electroless plating, distance between the two pillars, and annealing conditions affected the voids. Controlling the voids to minimize the voids can assist to improve the electrical and mechanical properties of the formed interconnects.

The inventors's experimental results show that electroless plating process can fill gaps between pillars. Each of the pillars examined was joined by the electroless process, although the gap varied from sample to sample. This ability to fill the void between near-mated pillars is an advantageous feature of the chip-to-substrate connection embodiments of the present invention. As a result, pillars do not have to physically contact or have uniform surfaces prior to electroless plating. Attempts were made to measure the contact resistance between the two electrolessly plated pillars. The resistance of the electroless copper region was less than the contact resistance to the pillar.

The inventors also analyzed bond strengths for copper pillar attachment joints. To carry out this analysis, the inventors subjected a formed copper interconnect structure bonded to two substrates to a shear force. The test was carried out by restraining a first substrate in a locked condition and applying a shear force to a second substrate to determine how much shear force was needed to decouple the substrates coupled together with an interconnection formed in accordance with embodiments of the present invention. The measured shear forces for separating the substrates is shown below in Table I.

TABLE I

| | Anneal | Anneal | Shear | Adhesion |
|---|---|---|---|---|
| Entry | Temp (° C.) | Duration | Force (N) | Layer |
| A | 400 | 1 Hour | 1.404 | Ti |
| B | 250 | 1 Hour | 4.840 | Ti |
| C | 250 | 1 Hour | 1.800 | Cr |

The sample annealed at about 400° C. (Entry A) comprised four copper pillars and sheared at a force of about 1.40 N. Since the polymer plating mold had been decomposed (was absent), it did not contribute to the adhesion of the two substrates. Based on the area of the four pillars (about 55 micrometers in diameter) the shear stress, corresponding to the adhesion of the titanium to the silicon dioxide, was about 148 MPa. The pillar-to-pillar electroless copper joint did not shear in any of the samples tested. To investigate anneal temperature effect, samples were annealed at different temperatures. Entry B shows the shear force for a set of four pillars plated and annealed at about 250° C. The sample again fractured at the metal-to silicon dioxide interface. However, Avatrel was present and contact was achieved between the two sides. Thus, some of the 4.84 N force was due to the Avatrel (polymer plating mold).

A second sample was prepared for 250° C. annealing (Entry C). However, chromium was used as the adhesion layer, rather than titanium. Also, the Avatrel did not bridge the two substrates. The separating shear force was about 1.80 N and the fracture occurred at the metal-to-silicon dioxide interface. This shear force value is higher than Entry A's most likely because the chromium provided greater adhesion. Again, the copper-to-copper joint did not rupture.

Finally, a sample with a titanium adhesion layer was annealed at about 200° C. This experiment resulted in a lower shear force, and the fracture occurred at the metal interface. Other lower anneal temperature samples also sheared at the copper-to-copper joint. Thus, the annealing temperature controls the copper grain size distribution, grain boundary character distribution, and crystallographic texture. Accordingly, it is desirable to have the anneal temperature be as low as possible, for semiconductor device purposes to enable compatibility with low cost organic components.

The embodiments of the present invention are not limited to the particular formulations, process steps, and materials disclosed herein as such formulations, process steps, and materials may vary somewhat. Moreover, the terminology employed herein is used for the purpose of describing exemplary embodiments only and the terminology is not intended to be limiting since the scope of the various embodiments of the present invention will be limited only by the appended claims and equivalents thereof. For example, temperature and pressure parameters may vary depending on the particular materials used. In addition, any metals capable of electro and electrolessly plating may be used in accordance with various embodiments of the present invention.

Therefore, while embodiments of this invention have been described in detail with particular reference to exemplary embodiments, those skilled in the art will understand that variations and modifications can be effected within the scope of the invention as defined in the appended claims. Accordingly, the scope of the various embodiments of the present invention should not be limited to the above discussed embodiments, and should only be defined by the following claims and all equivalents.

We claim:

1. An interconnection structure to connect components, the structure comprising:
a first portion extending from a first component, the first portion consisting of a single conductor; and
a joining section disposed between the first portion and a second component so that the first component and the second component are interconnected to each other to form an interconnect, the joining section consisting of the single conductor so that the interconnect consists only of the single conductor.

2. The structure of claim 1, further comprising a second portion extending from the second component and disposed between the second component and the joining section, wherein the first portion, the joining section, and the second portion form the interconnect, the second portion consisting of the single conductor so that the interconnect consists only of the single conductor.

3. The structure of claim 1, the single conductor being copper so that the interconnect connecting the first and second components is formed with copper.

4. The structure of claim 1, the joining section having a greater cross-sectional area than the first portion.

5. The structure of claim 1, wherein the joining section has a central axis that is substantially aligned with a central axis associated with at least one of the first portion and the second portion.

6. The structure of claim 2, the first portion defining a first axis and the second portion defining a second axis and wherein the interconnect is formed with the first axis being misaligned with the second axis.

7. The structure of claim 2, the first and second portions each having a length and wherein the length of the first section is greater than the length of the second section.

8. The structure of claim 2, wherein the joining section is metallically bonded to the first and second portions so that the first and second components are electrically coupled.

9. A method to interconnect components, the method comprising:
providing a first interconnect section coupled to a first component;
providing a second interconnect section coupled a second component; and
electrolessly depositing a metal between the first interconnect section and the second interconnect section to join the first interconnect section and the second interconnect section to form an interconnect that couples the first component to the second component.

10. The method of claim 9, wherein the first interconnect section and the second interconnect section are made from the same metal.

11. The method of claim 9, wherein at least one of the first interconnect section and the second interconnect section are made from substantially pure copper.

12. The method of claim 9, further comprising forming at least one of the first interconnect section and the second interconnect section by electroplating a metal.

13. The method of claim 9, further comprising electrolessly depositing copper between the first interconnect section and the second interconnect section.

14. The method of claim 9, further comprising forming at least one of a rounded end or a tapered end on at least one of the first interconnect section and the second interconnect section.

15. The method of claim 9, further comprising annealing the interconnect.

16. The method of claim 9, further comprising forming at least one of the first interconnect section and the second interconnect section to have an aspect ratio ranging from approximately 0.1 to 10.

17. In an integrated circuit package comprising a substrate and a wafer, a plurality of copper interconnects connecting the substrate to the wafer, each interconnect comprising:
a first copper component coupled to the substrate;
a second copper component located between the first copper component and the wafer so that the first copper component and the second copper component couple the substrate and the wafer.

18. The integrated circuit package of claim 17, each interconnect further comprising:
a third copper component disposed between the first copper component and the second copper component.

19. The integrated circuit package of claim 18, wherein the third copper component has a larger cross-sectional area than a cross-sectional area associated with at least one of the first copper component and the second copper component.

20. The integrated circuit package of claim 17, wherein each interconnect has a thickness and defines sidewalls having a length greater than the thickness.
